(19) United States
(12) Patent Application Publication
(10) Pub. No.: US 2010/0091257 A1
(43) Pub. Date: Apr. 15, 2010

(54) Optical Imaging System and Method for Imaging Up to Four Reticles to a Single Imaging Location

(75) Inventors: David M. Williamson, Tucson, AZ (US); Daniel G. Smith, Tucson, AZ (US); Michael B. Binnard, Belmont, CA (US); W.Thomas Novak, Hillsborough, CA (US); Eric P. Goodwin, Tucson, AZ (US)

Correspondence Address: LAWRENCE R. OREMLAND, P.C., 5055 E. BROADWAY BLVD., SUITE C-214, TUCSON, AZ, 85711, US

(73) Assignee: Nikon Corporation, Tokyo (JP)

(21) Appl. No.: 12/481,124

(22) Filed: Jun. 9, 2009

Related U.S. Application Data
(60) Provisional application No. 61/104,477, filed on Oct. 10, 2008.

(51) Int. Cl. G03F 7/20; G02B 27/32; G02B 17/08; G03B 27/32

(52) U.S. Cl. 355/66; 356/247; 359/364; 355/77

(57) ABSTRACT

A catadioptric optical imaging system and method is provided, in which up to four (4) reticles are imaged to a single imaging location (e.g. for imaging substrates), in a manner designed to provide high throughput, with a relatively high resolution, and with substrates whose size may approach 450 mm.

### RELATED APPLICATION/CLAIM OF PRIORITY

This application is related to and claims priority from provisional application Ser. No. 61/104,477, filed Oct. 10, 2008, which provisional application is incorporated by reference herein.

### BACKGROUND AND INTRODUCTION OF THE PRESENT INVENTION

In applicants' experience, in photolithographic systems and methods for imaging of substrates (e.g. in the creation of semiconductor wafers), there is a general need for high throughputs, while retaining high imaging resolution, particularly as wafer sizes get larger. To applicants' knowledge, the current state of the art essentially comprises imaging a single reticle to a substrate with an illumination field size of 26×5 mm. As wafer sizes get larger (e.g. with wafer diameters on the order of 450 mm), the ability to improve throughput (e.g. via system architecture, scanning and/or imaging techniques) is an important objective.

In concurrently filed applications of the assignee of the present invention, new and useful scanning and system architectures are provided, designed to (a) increase the width of the field that is scanned and imaged to a substrate, and (b) provide system architecture that images a pair of reticles to a single imaging location, and when combined with the new scanning concept, is designed to improve throughput. The present invention further develops those concepts, by providing a new and useful optical imaging system and method that provides additional versatility to the system architecture concept, and when used with the new scanning concept, is designed to further improve throughput in a system and method that images more than one reticle to a single imaging location.

More specifically, in the new scanning concept, (referred to by applicants as the “X-scan concept”) disclosed in concurrently filed application Ser. No. ______, entitled “Apparatus for Scanning Sites on a Wafer Along a Short Dimension of the Sites” (attorney reference 11269.151), which is assigned to the assignee of the present invention, and is incorporated by reference herein, which application claims priority on provisional applications Ser. No. 61/060,411, filed Jun. 10, 2008 (“System Architecture For Achieving Higher Scanner Throughput”), 61/078,251, filed Jul. 3, 2008 (“High NA Catadioptric Projection Optics For Imaging Two Reticles Onto One Wafer”) and 61/078,254, filed Jul. 3, 2008 (“X-Scanning Exposure System With Continuous Exposure”), all of which are incorporated by reference herein, a reticle and substrate are effectively rotated 90 degrees, to enable an illumination field size of 33 mm (width)×5 mm to be scanned and imaged to a substrate. In other words, the X-scan concept provides scanning of a reticle in what those in the art would refer to as the X direction, which has a larger width (and shorter length) than the Y direction which is a known scanning direction. That new scanning concept, when used with system architecture that is disclosed in concurrently filed U.S. application Ser. No. ______, entitled “Exposure Apparatus that utilizes Multiple Masks” (Attorney file number 11269.156), which is also assigned to the assignee of the present invention, and incorporated by reference herein, and which claims priority to U.S. provisional applications 61/060,411, 61/078,251 and 61/078,254 enables imaging a pair of reticles to a single imaging location, in a manner designed to enable higher throughput in the imaging of substrates.

### SUMMARY OF THE PRESENT INVENTION

The present invention is directed to an optical imaging system and method that further improves the versatility of an imaging optical system and method by which a plurality of reticles are imaged to a single imaging location, and when used with the new X-Scan scanning concept of concurrently filed U.S. application Ser. No. ______ (“Apparatus for Scanning Sites on a Wafer Along a Short Dimension of the Sites”, attorney reference 11269.151), and the system architecture concept of concurrently filed U.S. application Ser. No. ______ (“Exposure Apparatus that utilizes Multiple Masks”, Attorney file number 11269.156), provides still additional improvements in versatility and throughput, in the manner in which reticle scanning and imaging to a single imaging location can be effected.

More specifically, the present invention provides a catadioptric imaging optical system and method, which is designed to image up to 4 reticles to a single imaging location (e.g. a substrate), in a manner that (a) provides versatility (in terms of the manner in which the 4 reticles can be imaged to the single imaging location, (b) effectively enables substantially “continuous” scanning/imaging (in the sense that it is designed to eliminate downtime in the scanning/imaging of a number of up to four reticles to a single imaging location), (c) further increases throughput (particularly when used with the X-Scan concept, with relatively high resolution (e.g. a numerical aperture, NA, of 1.35 or more), and (d) which is designed to further improve the manner in which larger substrates can be imaged (e.g. to produce wafers with diameters on the order of 450 mm).

The present invention provides an imaging optical system comprising up to four reticles, and a catadioptric imaging optics system configured to image a selected one or a plurality of the four reticles to a single imaging location. In the practice of the method of the present invention, up to 4 of the reticles are imaged to the single imaging location via the catadioptric imaging optics system.

Preferably, four reticles are grouped into two pairs of reticles, and the catadioptric imaging optics system is configured to image a selected one of each of the two pairs of reticles to the single imaging location. Also, the catadioptric imaging optics system comprises a pair of switching mirrors, each of which is associated with one of the two pairs of reticles. Each of the switching mirrors has a pair of orientations, and when a switching mirror is in one of the pair of orientations, it is oriented to image one of its associated pair of reticles to the single imaging location.

In accordance with the X-Scan concept, each of the reticles is oriented to be scanned in a manner that enables image fields 33 mm in width to be imaged from the reticle to the single imaging location. Moreover, the catadioptric imaging optics system is configured to enable image fields (33 mm in width) from 2 of the reticles to be imaged to the single imaging location in side by side relation with spacing of 5 mm or less between the image fields. Also, the catadioptric imaging optics system is configured to enable reticles with different patterns to be sequentially imaged to the single image location, to produce on a substrate what is known in the art as a “double exposure).

In addition, the catadioptric imaging optics system is configured to enable “substantially continuous” imaging of up to 4 reticles to the single imaging location as a substrate is moved in a single predetermined direction in relation to the single imaging location. Moreover the catadioptric imaging optics system is configured to enable substantially continuous imaging of up to 4 reticles to the single imaging location as a substrate is moved in each of a pair of opposite predetermined directions in relation to the single imaging location. Thus, the present invention is designed to accommodate substrate movement patterns that are substantially continuous in one direction in relation to the single imaging location, and also substrate movement patterns that are boustrophedonic (i. e. in predetermined back and forth movement patterns) relative to the single imaging location.

In a catadioptric imaging optics system, according to the principles of the present invention, there are two arms and a common leg. Each arm has (i) at least one concave mirror, (ii) at least one intermediate image in proximity to a fold mirror, to allow light to be incident on and reflected from the concave mirror without obscuration, and (iii) at least one switchable fold mirror, in proximity to a pupil plane, and the common leg has at least one further intermediate image in proximity to a v-mirror that combines the beams from two arms, where the beam size and shape facilitates the folding of the beams perpendicular to the plane of the two arms.

In addition, in a preferred embodiment, the catadioptric imaging optics system comprises optics with the prescriptions of FIGS. 6a-6d. Moreover, the imaging optical system and method of the invention is particularly useful with a catadioptric imaging optics system that is configured with a numerical aperture of 1.35. It should be noted that these preferred embodiments do not restrict the scope of the invention.

Also, an optical imaging system and method according to the principles of the present invention is particularly useful with an argon fluoride (ArF) immersion photolithographic scanner.

It should be noted that imaging to a “single imaging location” means a single location where a “substrate” photoresist is “imaged” (also referred to as “exposed” or “printed”) with a pattern that enables the substrate to be used in the creation of a semiconductor wafer, thin-film read head, flat panel display, or another device. Thus, the terms “single imaging location”, “substrate” and/or “wafer”, may each be used in this application, in referring to the foregoing concept. Also, the substrate is generally divided (optically) into sections referred to as “sites”, and each of those dies is imaged in the manner described herein, so that the plurality of sites (which would form the wafer) can ultimately be separated into semiconductor “shots”. In addition, the concept of “continuous imaging”, as used in this application, contemplates that a substrate (that is carried on a stage, as is well known to those in the art) moves past the single imaging location (generally at a constant velocity) and also allows for the fact that there may be some slowdowns (or even stoppages) of the movement of the substrate as the stage changes direction, returns to an initial position, etc.

Other features of the present invention will be apparent from the following detailed description and the accompanying drawings and exhibits

### BRIEF DESCRIPTION OF THE DRAWINGS AND EXHIBITS

FIG. 1 is a schematic illustration of the overall structure and operating principles of a catadioptric imaging optical system and method, according to the principles of the present invention;

FIG. 2 is a schematic, three dimensional illustration of the catadioptric optics for an imaging optical system and method, according to the principles of the present invention;

FIGS. 3 and 4 schematically illustrate 2 options for implementing the switching mirror aspect of the imaging optical system and method, according to the principles of the present invention;

FIG. 5 is a schematic illustration of a portion of a catadioptric imaging optical system and method, according to the principles of the present invention, that is useful as a reference for the optics prescriptions of FIGS. 6a-6d;

FIGS. 6a-6d provide preferred prescriptions for the optics of the portion of the catadioptric imaging optical system of FIG. 5;

FIG. 7 is a schematic illustration of the manner in which a substrate can be imaged, with a system and method according to the principles of the present invention, with a substrate that is moved past a single imaging location in a “boustrophedonic” pattern (where the substrate moves in back and forth patterns in relation to the single imaging location, and the substrate is substantially continuously imaged from the 4 reticles as the substrate is moved in each of the back and forth patterns in relation to the imaging location);

FIG. 8 is a schematic timing diagram for the imaging of the four reticles to the single imaging location, with the boustrophedonic substrate movement pattern of FIG. 7; and

FIG. 9 is a schematic illustration of the manner in which a substrate can be imaged, with a system and method according to the principles of the present invention, as the substrate is moved past a single imaging location in a substantially continuous pattern of movement in a single direction (with this schema, the stage of the substrate would return to an initial position to begin another continuous pattern of movement past the single imaging location in the same single direction).

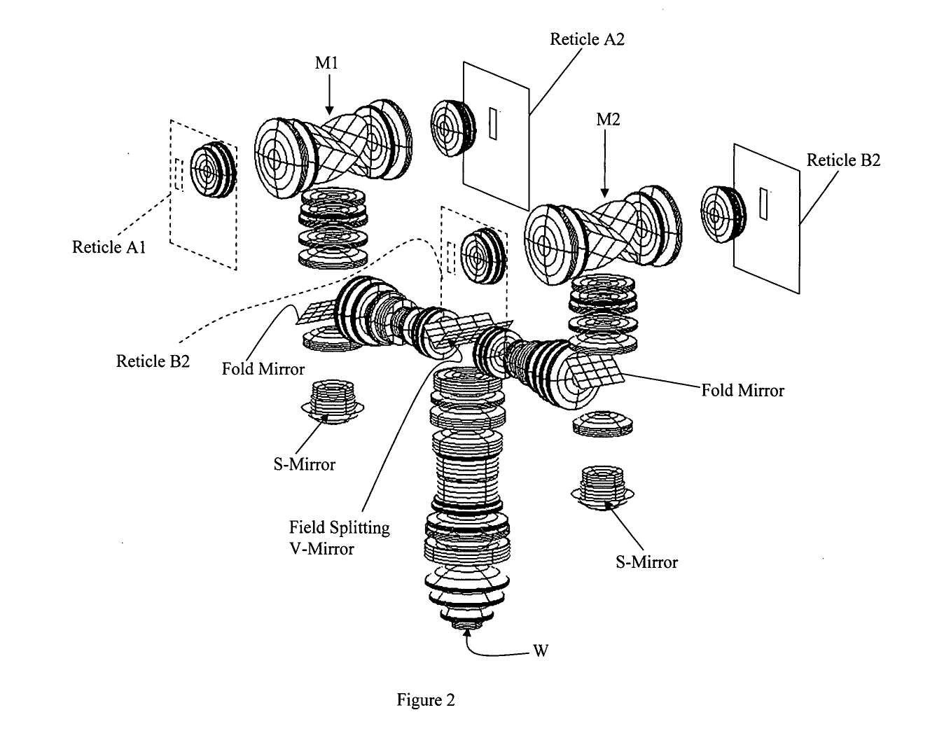

Exhibit A is a schematic three dimensional illustration of the optics of FIG. 2, with some ray lines shown thereon; and

Exhibit B is a schematic three dimensional illustration of a system according to the present invention, with some ray lines shown thereon.

### DETAILED DESCRIPTION

As described above, the present invention relates to a catadioptric imaging system and method that is configured to simultaneously image up to four (4) reticles to a single imaging location. That single imaging location is generally a location where a substrate (e.g. for use in creating a semiconductor wafer) that has a photoresist is imaged and then the image is “developed” to produce the pattern(s) for the wafer. Thus, in this application, reference to a “single imaging location” is intended to mean the type of imaging location where a substrate would be imaged in the formation of the patterns that are used to produce a semiconductor wafer.

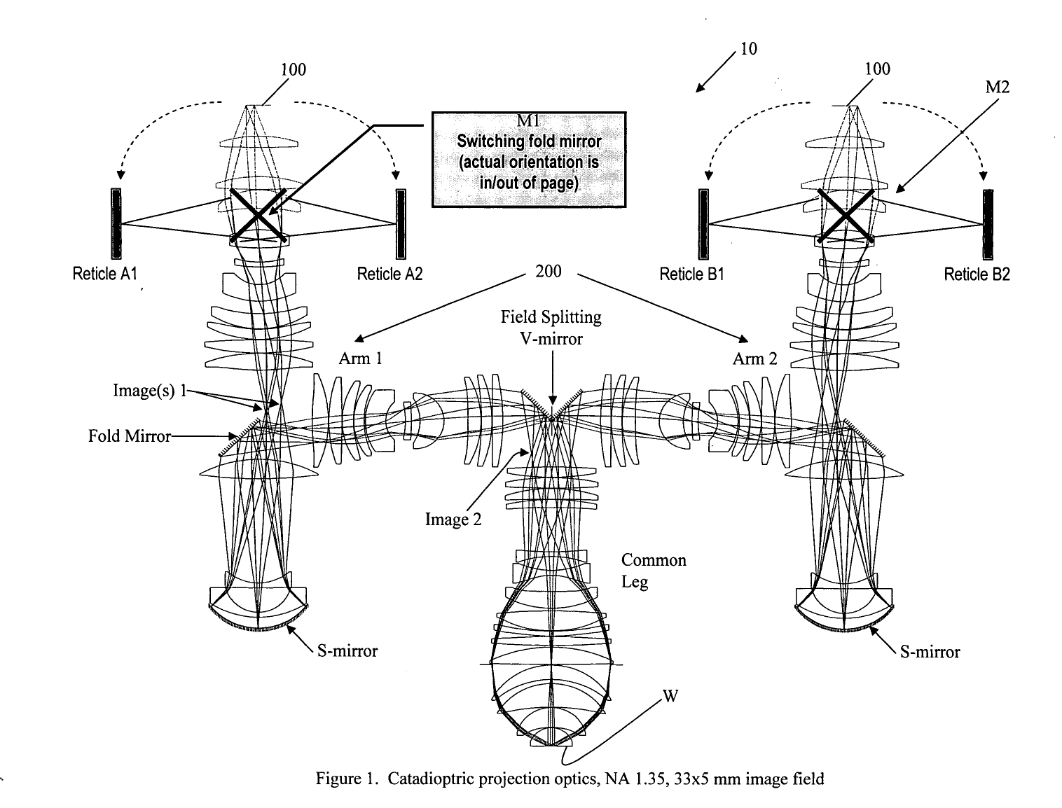

The imaging optical system 10 comprises up to four reticles (Reticle A1, Reticle A2, Reticle B1, Reticle B2), and a catadioptric imaging optics system 200 configured to image a selected one or a plurality of the four reticles to a single imaging location W. Preferably, four reticles are grouped into two pairs of reticles, and the catadioptric imaging optics system 200 is configured to image a selected one of each of the two pairs of reticles to the single imaging location. In FIG. 1, Reticle A1 and Reticle A2 form one of the pairs of reticles, and Reticle B1 and Reticle B2 form the other pair of reticles. Also, the catadioptric imaging optics system 200 comprises a pair of switching fold mirrors M1 and M2, each of which is associated with one of the two pairs of reticles. Each of the switching fold mirrors M1, M2, has a pair of orientations, and when a switching mirror is in one of the pair of orientations, it is oriented to image one of its associated pair of reticles to the single imaging location W.

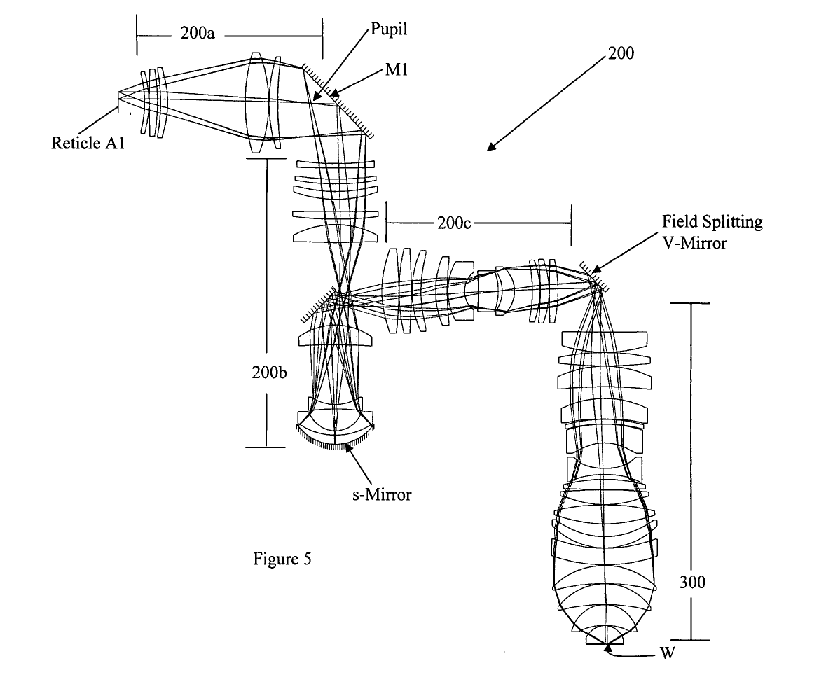

As will be appreciated from FIGS. 1 and 5, a reticle that is being imaged to the single imaging location W is imaged by optics that include (a) an imaging “arm” comprising an array of optics 200a (identified in FIG. 5) between the reticle and the switching fold mirror, and arrays of optics 200b and 200c (identified in FIG. 5) on one side of a field splitting V mirror, and a “leg” comprising an array of optics 300 (identified in FIG. 5) between the field splitting V mirror and the single imaging location W. Thus, the “arms” of the catadioptric imaging optical system would include one “arm” (referred to later as Arm 1) comprising the optics arrays (200a, 200b, 200c) on the left side of the field slitting V mirror and another arm (referred to later as Arm 2) comprising optics arrays similar to the optics arrays of Arm 1, but on the right side of the field splitting V mirror.

In the practice of the method of the present invention, up to 4 of the reticles are imaged to the single imaging location W, via the catadioptric imaging optics system 200. As a reticle is being scanned, it would be illuminated in ways well known to those in the art. Two switching mirrors (M1, M2) select the object field on one reticle from each of two pairs of reticles, so that two reticles can be imaged onto two adjacent fields at the imaging location W. It will also be recognized from the illustrated rays, that in the system of FIG. 1, the image from Arm 1 (which is on the left side of the field splitting V mirror) will be directed to the right side of the optical axis at the single imaging location W, and the image from Arm 2 (which is on the right side of the field splitting V mirror) will be directed to the left of the optical axis at the single imaging location W.

In accordance with the X-Scan concept, each of the reticles is preferably oriented to be scanned in a manner that enables image fields (e.g., 33 mm in width) to be imaged from the reticle to the single imaging location by scanning along the short dimension of the exposure site. It should be noted that depending on the specific application for a lithography machine, a “Y-Scan” exposure pattern, in which the scanning direction is along the longer dimension of the exposure site and the illumination field size is not as wide (e.g., 26 mm in width), is also within the scope of this invention. Moreover, the catadioptric imaging optics system 200 is preferably configured to enable image fields from 2 of the reticles to be imaged to the single image location in side by side relation with spacing of 5 mm or less between the image fields. The fields may alternatively be more than 5 mm apart.

In addition, the catadioptric imaging optics system is configured to enable substantially continuous imaging of up to 4 reticles to the single imaging location as a substrate is moved in a single predetermined direction in relation to the single imaging location. Moreover, the catadioptric imaging optics system is configured to enable substantially continuous imaging of up to 4 reticles to the single imaging location as a substrate is moved in each of a pair of opposite predetermined directions in relation to the single imaging location. Thus, the present invention is designed to accommodate substrate movement patterns that are substantially continuous in one direction in relation to the single imaging location, and also substrate movement patterns that are boustrophedonic (i. e. in predetermined back and forth movement patterns) relative to the single imaging location. This aspect of the system and method of the present invention is described further below.

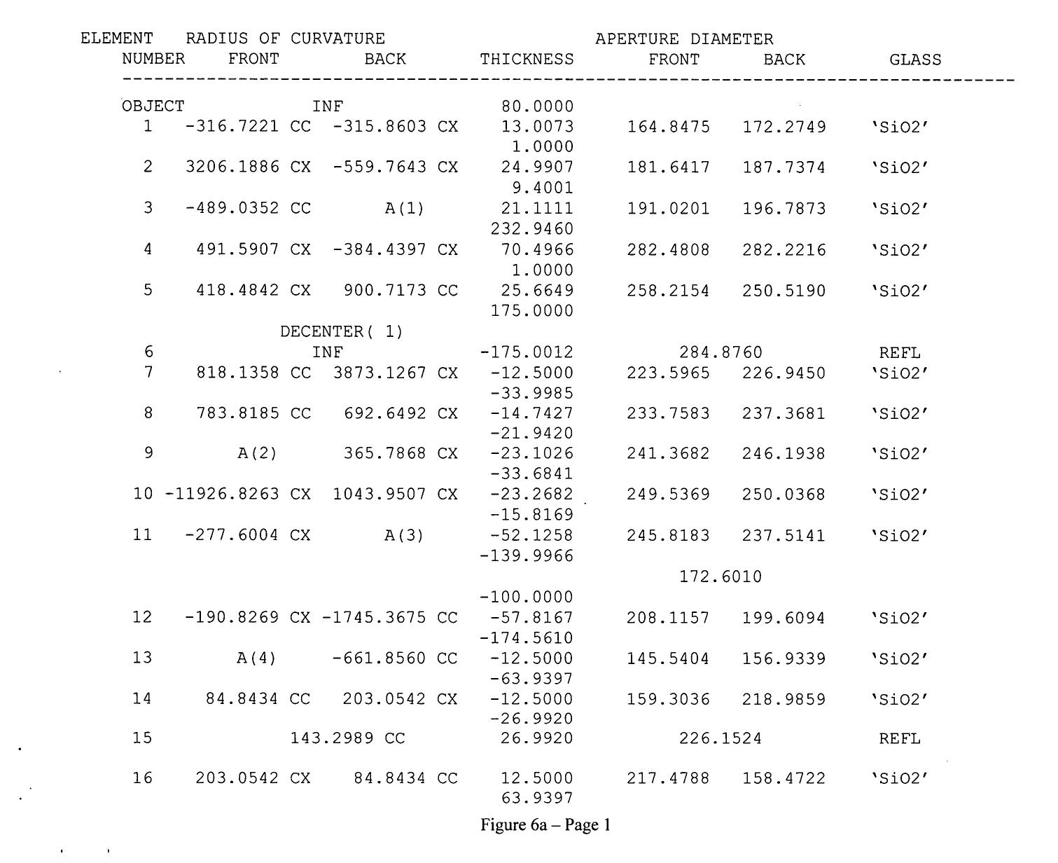

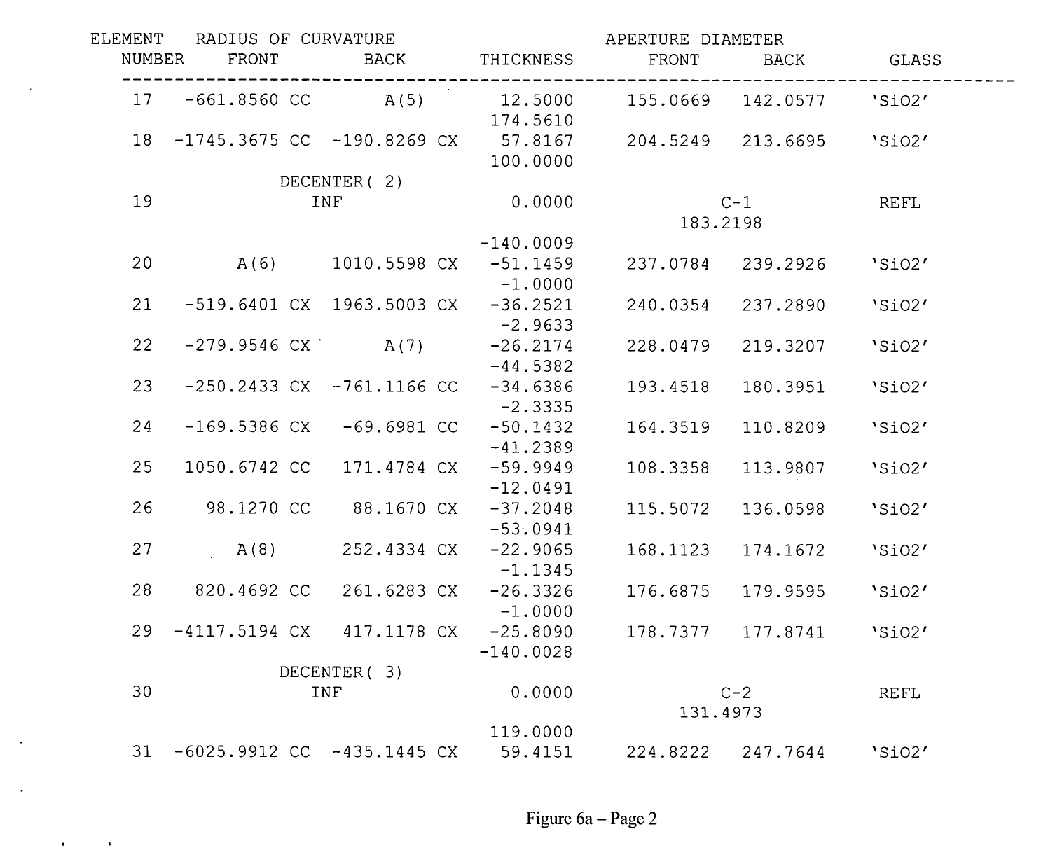

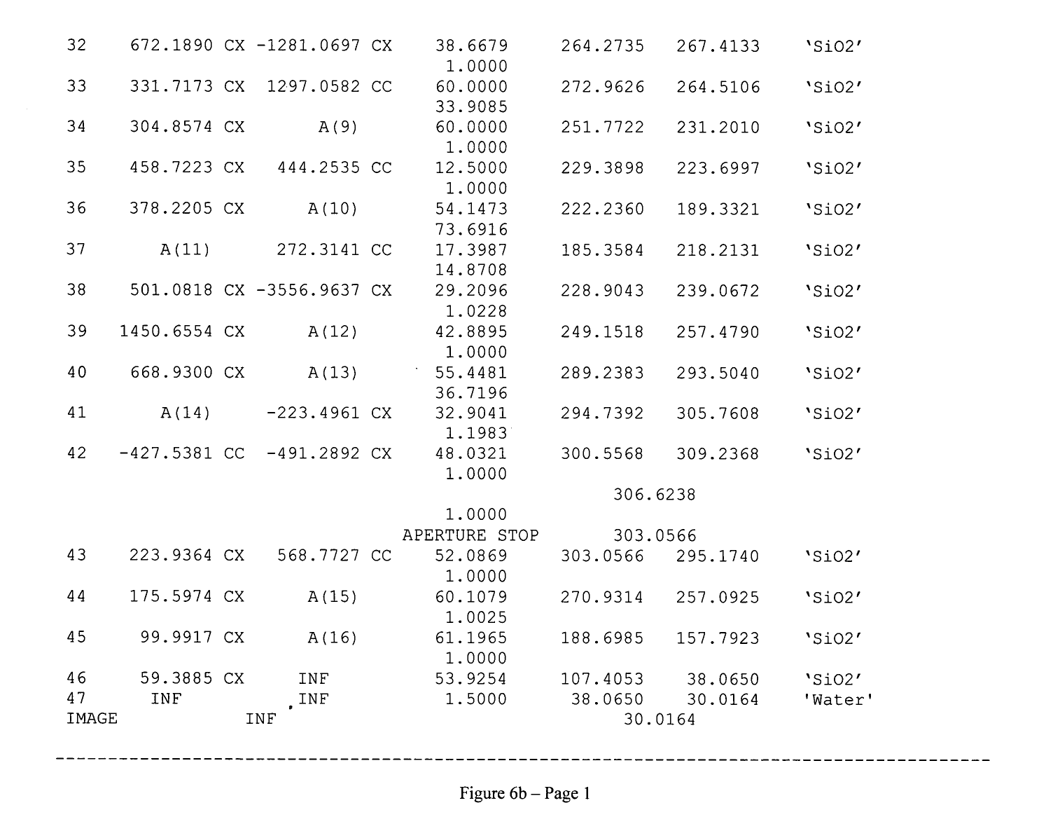

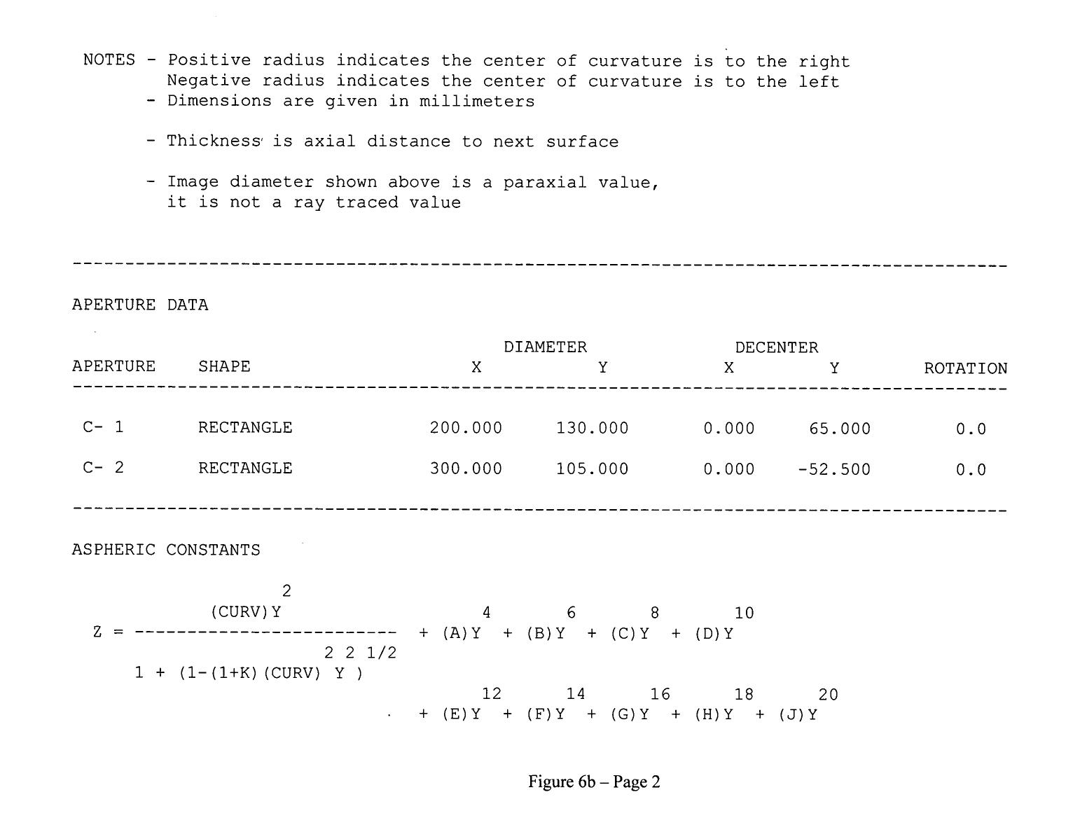

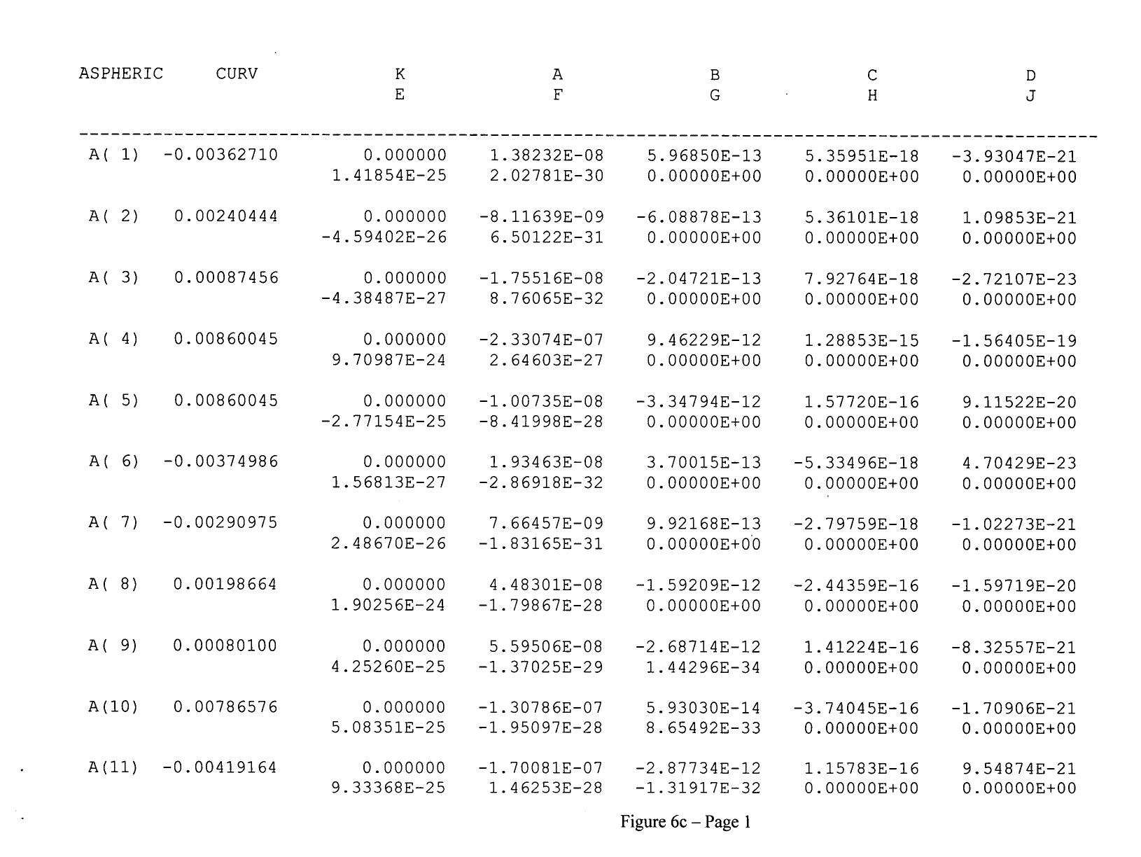

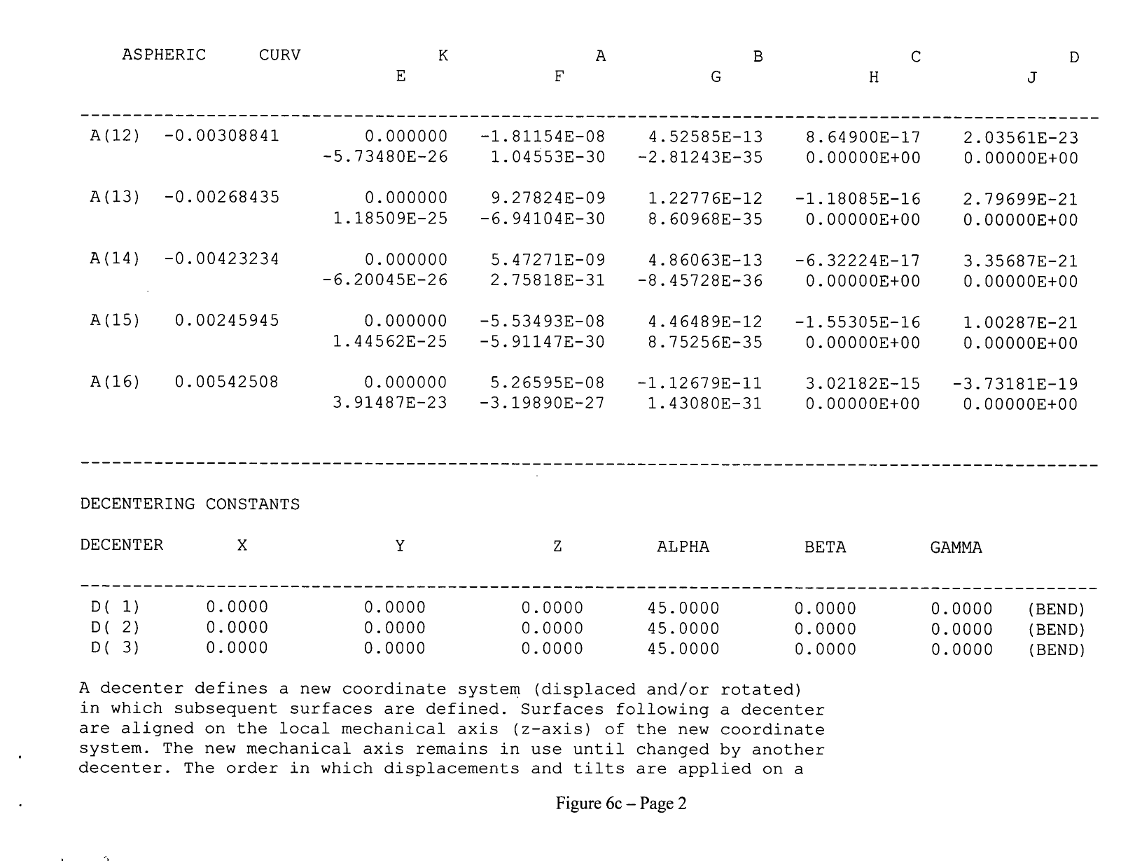

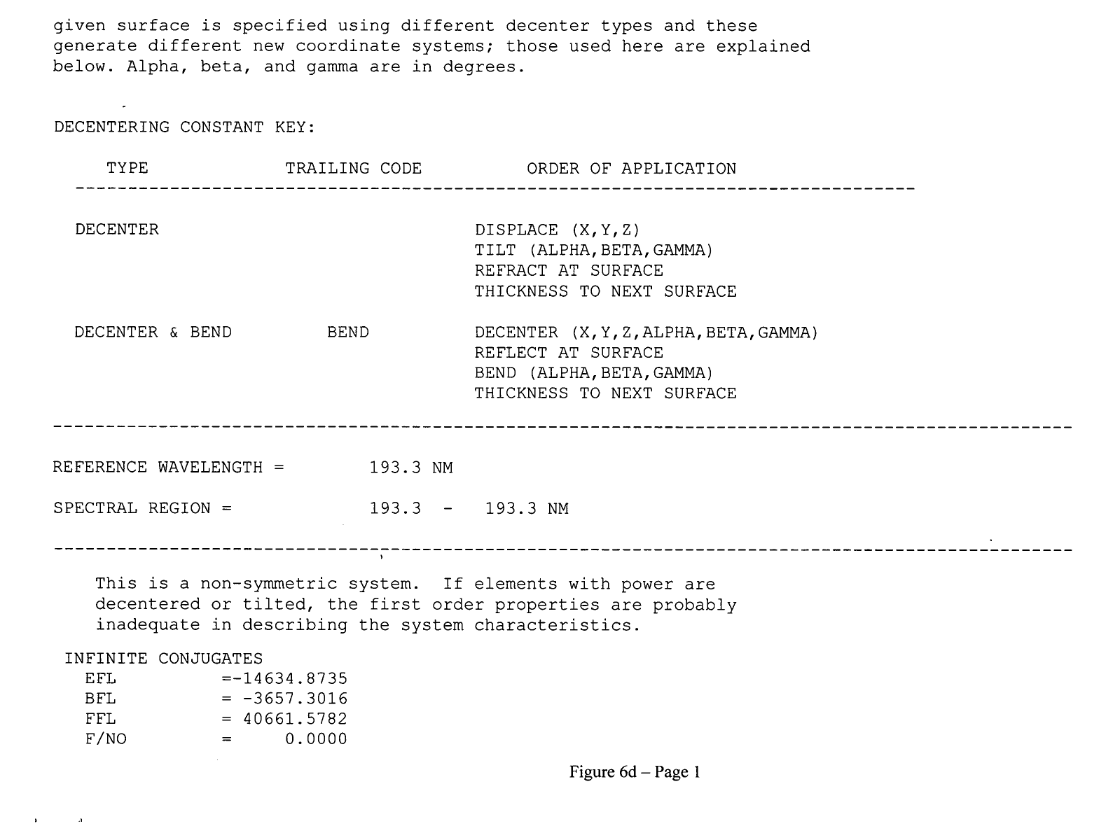

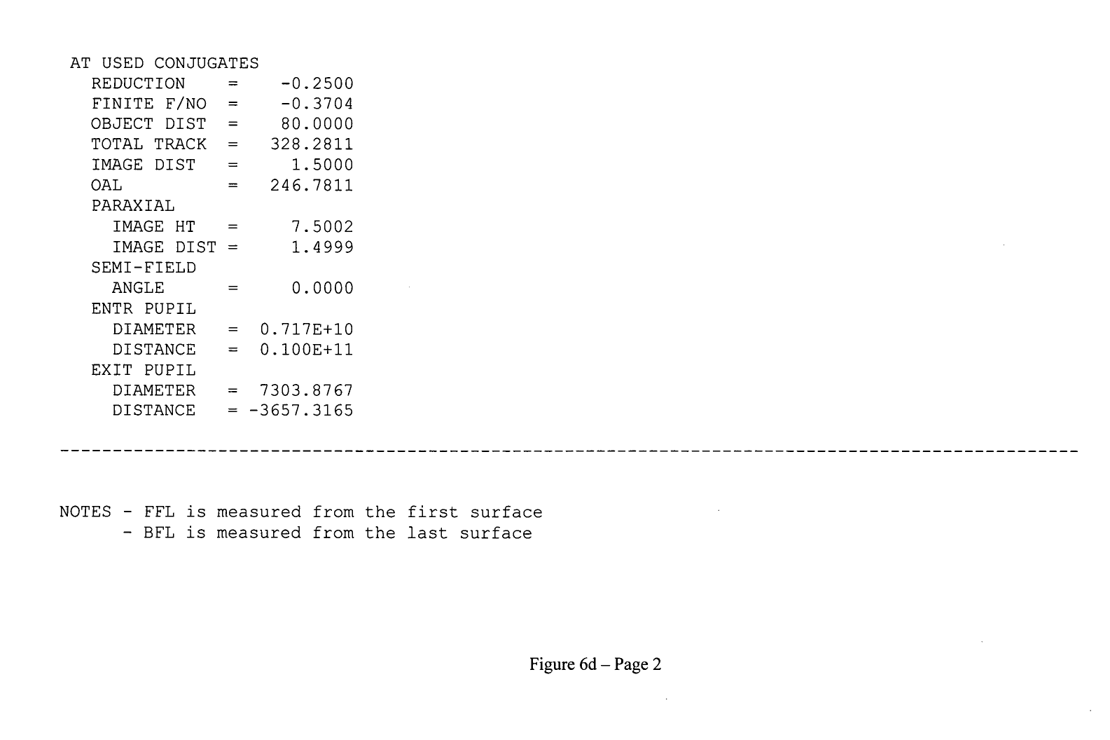

The optics forming an “arm” and the common “leg” of the catadioptric imaging optics preferably have the prescriptions shown and described FIGS. 6a-6d. More specifically, in FIGS. 6a, 6b
1. objects 1-5 describe the prescriptions for the array of optical components 200a,
2. object 6 describes the prescription for switching mirror M1,
3. objects 7-18 describe the prescriptions for the array of optical components 200b (it will be recognized by those in the art that objects 12-14 and 16-18 describe the same components as the image is transmitted to and from the spherical “S-mirror”, which is object 15, and object 19 describes the prescription for the mirror that reflects the image to the array of optical components 200c),
4. objects 20-29 describe the prescriptions for the array of optical components 200c,
5. object 30 describes the prescription for the field splitting V-mirror,
6. objects 31-46 describe the prescriptions for the array of optical components 300, and
7. object 47 describes the prescription for the a substrate at the image plane of the system.

Since the optics arrays of each “arm” of the catadioptric imaging optics will have identical prescriptions to arrays 200a, 200b and 200c, as described in FIGS. 6a-6d, the foregoing prescriptions for the optics of one of the arms and the common leg of the imaging optical system provides the prescriptions for the optics of the entire imaging optical system of FIG. 1.

The imaging optical system and method of the invention is particularly useful with a catadioptric imaging optics system that is configured with a numerical aperture of 1.35. The imaging optical system and method of this invention is preferably intended to form the imaging optical system for an ArF Immersion photolithographic scanner. Of course, other numerical apertures and illumination wavelengths are within the scope of this invention.

In the practice of a method, according to the principles of the present invention, one switching mirror (M1) selects an object field from either reticle A1 or A2. A second, independent, switching mirror (M2) selects another object field from either reticle B1 or B2. This allows two reticles, i.e. either A1 or A2 and either B1 or B2 to be imaged to the single imaging location W, in side by side relation. The two selected reticles are imaged to the single imaging location W via the Arms 1 and 2, the field splitting V mirror and the common set of optics forming the vertical “leg” 300 of the catadioptric imaging optics system.

With the X-Scan concept, and the preferred prescriptions for the optics of the imaging optics system (as described in FIGS. 6a-6d) rectangular fields, each 33 (width)×5 mm are imaged to the single imaging location W, e.g. adjacent to each other, with spacing between them of 5 mm or less. As will be clear from the description herein, each reticle that is being imaged can be selected from the pair of reticles (A1 or A2 and B1 or B2), allowing the imaging of up to four independent reticles to the single imaging location W.

As will be further clear to those in the art, the illustration of FIG. 1 shows that the pair of reticles that are associated with each switching mirror M1, M2, are effectively in place of a single reticle (shown schematically at 100), which would normally be used in the novel catadioptric optic imaging system as described in concurrently filed U.S. application Ser. No. ______, (“Exposure Apparatus that utilizes Multiple Masks”, Attorney file number 11269.156), which is incorporated by reference herein. In addition, each pair of reticles (i.e. A1, A2, and B1, B2) would be oriented perpendicular to the plane of FIG. 1 (as will be appreciated by the three dimensional images of FIG. 2, and exhibits A and B). Also, the figures schematically show the orientations of one of the switching mirrors M1, M2 to the pairs of reticles and to certain of the other reflective components (e.g. S-mirrors and field splitting V-mirror) in an optical imaging system according to the present invention.

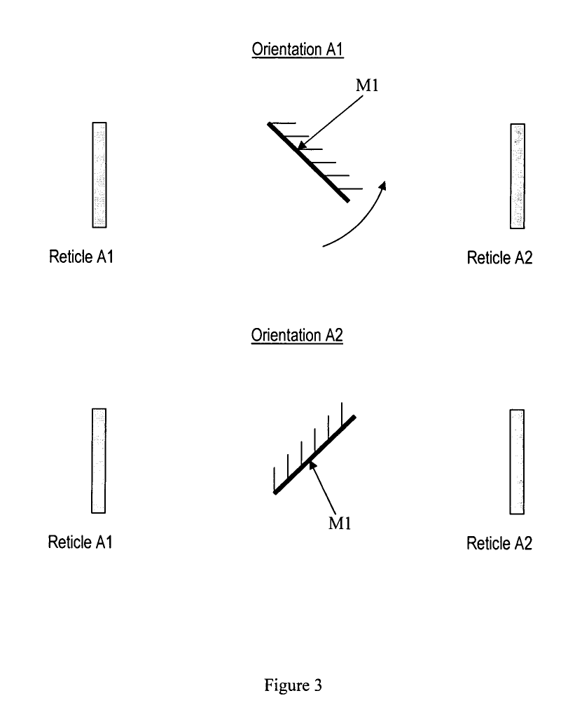

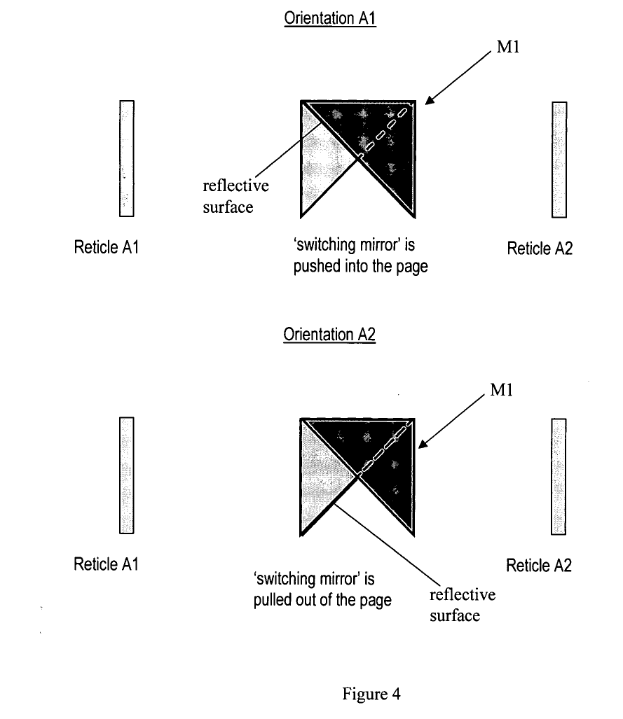

Although the switching mirrors M1, M2 in FIG. 1 appear to interfere mechanically with some of the lens elements of this lens design, it should be clear to those in the art that the optics in the system design can be optimized to remove this interference In fact, the lens design of FIG. 5 has removed the mechanical interference between the switching mirrors M1 and M2 and any nearby lens elements. FIGS. 3 and 4 schematically illustrate 2 specific implementations of the switching mirror aspect of the present invention. In the embodiment of FIG. 3, there is a single mirror M1 that rotates 90 degrees to switch orientation between reticles A1 and A2 (the orientations being shown as Orientation A1 and Orientation A2). In the embodiment of FIG. 4, a two prism arrangement is shown, in which there are two mirror surfaces on the hypotenuse of each triangle in the figure, oriented 90 degrees from each other. The 2-prism assembly moves in and out of the page to change orientation. The prism surface that is operative to reflect light from a respective reticle for each of the two orientations is identified as the “reflective surface” and is the reflective surface that is used in that orientation. This embodiment may be easier to accurately realize mechanically, although more mass is involved that must be moved, in relation to the embodiment of FIG. 3. Also, rather than 2 prisms, two mirror surfaces can be provided, that would move in and out of the page to change orientation.

With a catadioptric imaging optical system and method according to the preferred embodiment (using e.g. the X-Scan concept and the optics prescriptions of FIGS. 6a-6d), the imaging of two, adjacent, larger field sizes allows for the possibility of high throughputs, particularly as wafer sizes approach 450 mm, while retaining the high resolution made possible by an extremely high NA of 1.35, using ArF water immersion.

The switching mirrors M1, M2, also allow for a relatively fast change of reticles imaged to the single imaging location W, without loading and unloading reticles from their stages. This is advantageous in improving the system throughput, including in situations such as double exposure, where a final wafer pattern is formed from two sequential exposures of a pair of different reticle patterns at the single imaging location.

It should also be noted that each arm of the catadioptric imaging optics system has (i) at least one concave mirror (e.g. the concave S-mirrors shown in FIGS. 1 and 5), (ii) at least one intermediate image in proximity to a fold mirror, to allow light to be incident on and reflected from the concave mirror without obscuration (in FIG. 1, intermediate image(s) 1 are shown in proximity to a fold mirror between the mirror M1 and the concave s-mirror), and (iii) at least one switchable fold mirror (M1, M2), in proximity to a pupil plane (the location of the pupil plane is shown in FIG. 5), and the common leg has at least one further intermediate image in proximity to a v-mirror that combines the beams from two arms (in FIG. 1, the further intermediate image is shown at image 2, in proximity to the V-fold mirror), where the beam size and shape facilitates the folding of the beams perpendicular to the plane of the two arms (in the catadioptric imaging optics system disclosed herein, it will be noted that at or near the pupil, the beam shape is almost circular, so a fold mirror [e.g. the switchable fold mirror M1] will be about the same size whether the beam is folded in the y or x planes, i.e. in the long or short direction of the field, whereas away from the pupil, the beam size becomes elongated in the direction of the longer field dimension, but the catadioptric imaging optics system described herein provides enough clearance for the fold mirror to fold the system in the long field direction, as will be clear to those in the art).

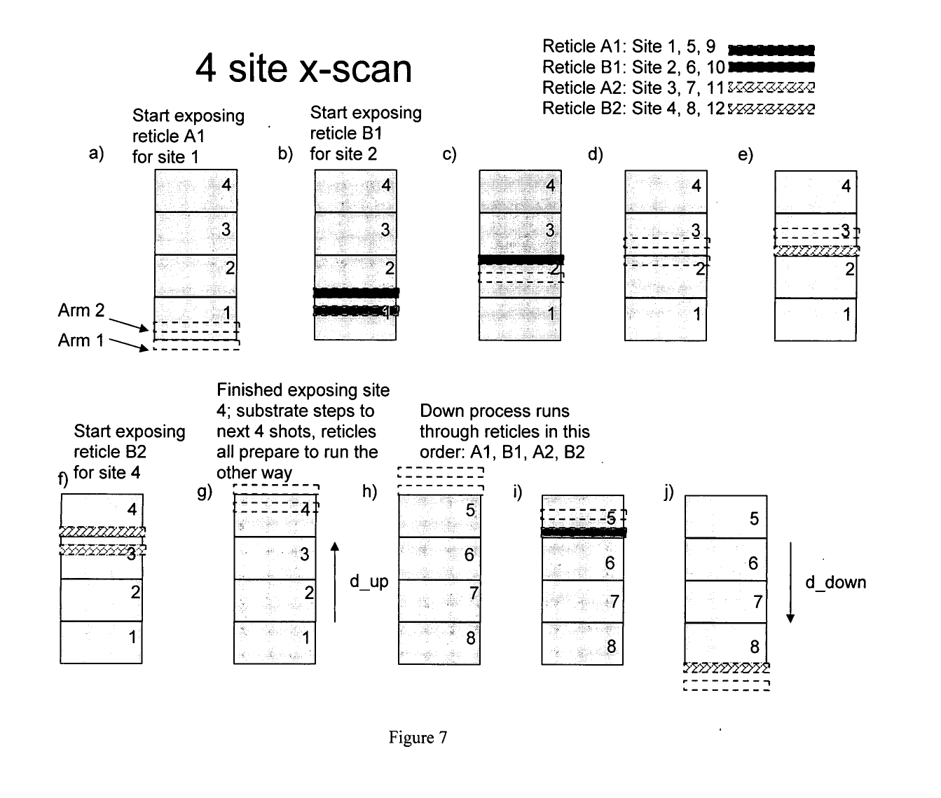

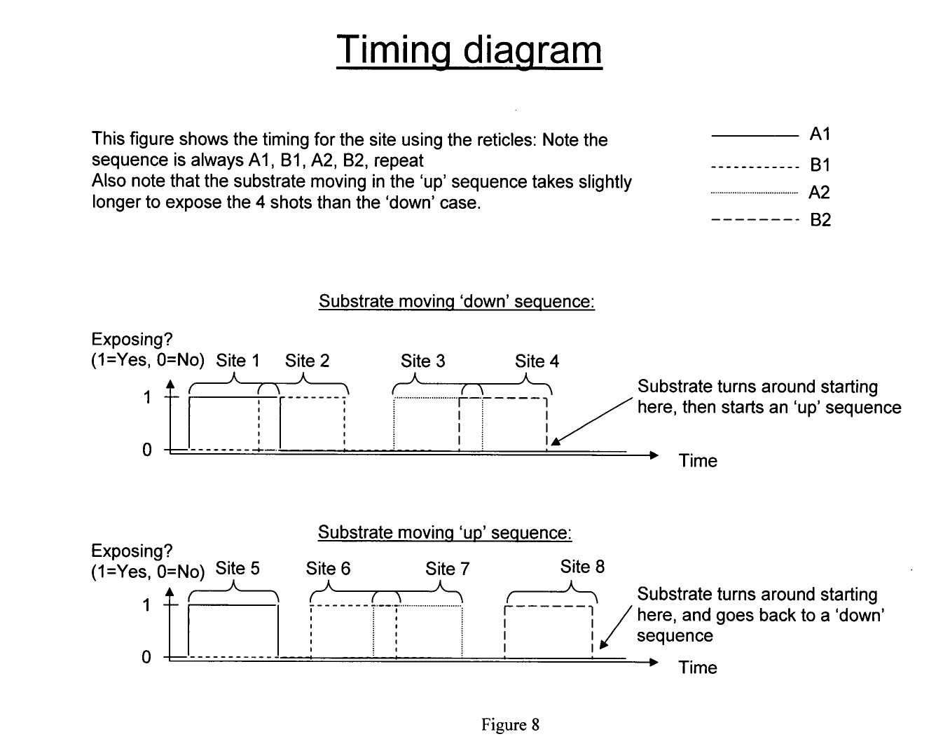

FIGS. 7 and 8 schematically illustrate the manner in which a pair of reticles is imaged to a single imaging location, with the X-Scan concept, the catadioptric imaging optics system described herein, and with a boustrophedonic (back and forth) movement of a substrate (wafer) in relation to the single imaging location.

In the imaging sequence of FIG. 7, and the timing diagram of FIG. 8, the substrate is moving with a constant velocity past the single imaging location during exposure. In FIG. 7, the imaged fields from the reticles appear to move, but in fact they are fixed at the single imaging location, and the substrate (with the die portions illustrated) moves past the single imaging location, so that what is shown is the relative movements of the dies and the image fields, as the substrate is moved past the single imaging location.

Thus, in the imaging sequence of FIGS. 7 and 8, identified by the sequence a) through g) below, which is for a boustrophedonic substrate movement pattern:
a) The substrate is moving down (as seen in FIG. 7) and about to start exposing die 1 with reticle A1 through Arm 1 of the imaging optical system. Arm 2 is not exposing anything yet.
b) In between a) and b), site 1 has been exposing using reticle A1, imaged through Arm 1. In b), site 2 has started exposure through arm 2 using reticle B1. Both site 1 and site 2 are exposed simultaneously for a short period of time, as shown in b, until site 1 is complete.
c) Site 2 is nearly finished exposing. Meanwhile, the switching mirror between reticle A1 and A2 is switching over to the other reticle so that arm 1 will be ready to expose site 3 using reticle A2.
d) Site 2 is finished, and site 3 is just about to start printing. Neither arm is imaging until arm 1 starts exposing site 3 with reticle A2.
e) Site 3 has just started printing. The switching mirror in arm 2 (for changing between the two B reticles) is in the process of switching.
f) Site 4 is now starting to print with reticle B2 on arm 2. Again, both arms are imaging simultaneously for some short time.
g) Since f), site 3 has completed, and in g), site 4 has just finished. The substrate has now finished scanning down for this set of 4 sites, and neither arm is printing. All 4 reticles were each used once in exposing the 4 sites, in this order: A1, B1, A2, B2.
h) Between g) and h), the wafer moves over to the next column of sites, and scans a little bit further in the scan direction to position arm 1 (with reticle A1) such that it is ready to print Also, between g) and h), the switching mirrors move back to the original position, in preparation of exposing reticles A1 and B1. All 4 reticles will now scan in the opposite direction compared to the direction they moved to expose sites 1 through 4. In h), the wafer is just starting to scan up.
i) Reticle A1 exposes site 5 through arm 1, where it is nearly finished in i). Sites 5-8 are exposed from i) through j), using the reticles in the same A1, B1, A2, B2 sequence.
j) Site 8 is almost done exposing using reticle B2 in arm 2, and the sequence can start back at the beginning, as shown in part a).
Alternatively, to reduce the frequency of switching the M1 and M2 folding mirrors, the “down” scans could use the reticles in a sequence of A2, B2, A1, B1. The tradeoff required for this sequence is increasing the reticle stage acceleration.

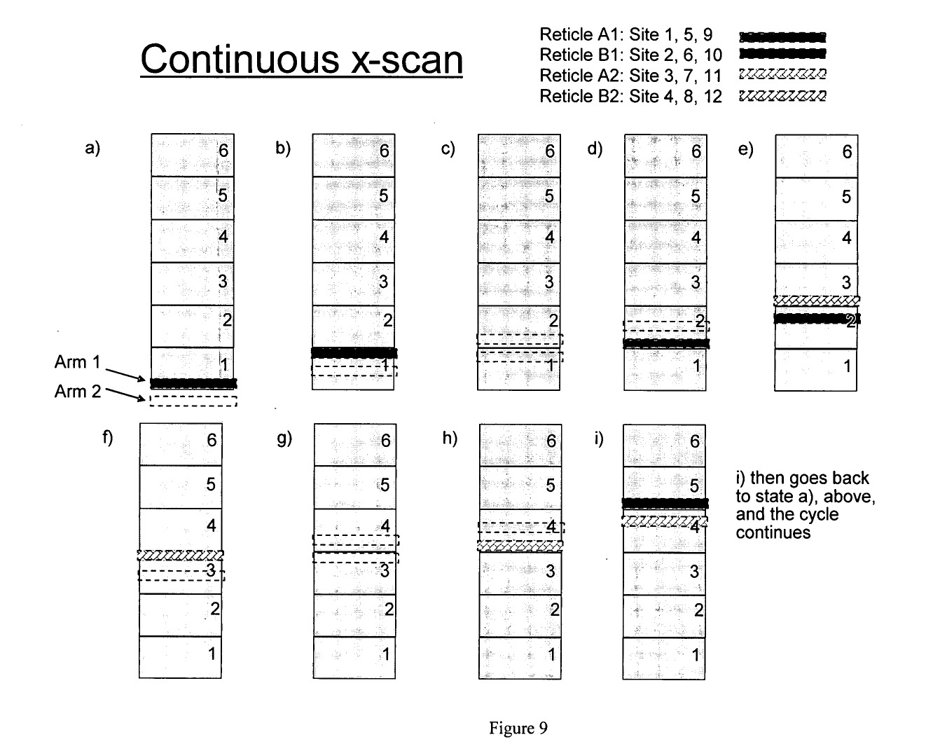

FIG. 9 is a schematic illustration similar to FIG. 7, but illustrating the manner in which one of each of two pairs of reticles are imaged to a single imaging location as a substrate is moved in one continuous movement in one direction in relation to the single imaging location. Rather than reversing its movement pattern, as in the boustrophedonic pattern of FIG. 7, after exposing four sites using the four reticles, the substrate would continue to move continuously in the same direction. First, in a similar manner to FIGS. 7 and 8, sites 1-4 are exposed using reticles B1, A1, B2, A2, respectively. Exposure of site 5 using reticle B1 begins slightly before the completion of site 4's exposure. In this sequence, the substrate moves continuously across the full width of the substrate, and the four reticles are repetitively exposed in an B1, A1, B2, A2 pattern. Form the description of the imaging sequence of FIG. 7, and the illustration of FIG. 9, it will be clear to those in the art as to the manner in which the continuous imaging of FIG. 9 is affected.

Applicants note that the imaging sequence of FIGS. 7 and 8 is currently considered best for throughput given the current state of the art for reticle stage acceleration and wafer stage velocity in an immersion system. If the reticle stage acceleration can be increased, then the continuous imaging sequence of FIG. 9 (across the substrate diameter) is likely to produce the best throughput. Therefore, it is not straightforward to make a general statement about the best sequence to use for all cases, rather it depends on the specific requirements for a particular exposure machine.

Thus, as will be clear from the foregoing detailed description, the present invention provides an imaging optical system comprising up to four reticles, and a catadioptric imaging optics system configured to image a selected one or a plurality of the four reticles to a single imaging location. In the practice of the method of the present invention, up to 4 of the reticles are imaged to the wafer via the catadioptric imaging optics system. Preferably, four reticles are grouped into two pairs of reticles, and the catadioptric imaging optics system is configured to image a selected one of each of the two pairs of reticles to the single imaging location. Also, the catadioptric imaging optics system comprises a pair of switching fold mirrors, each of which is associated with one of the two pairs of reticles. Each of the switching fold mirrors has a pair of orientations, and when a folding mirror is in one of the pair of orientations, it is oriented to image one of its associated pair of reticles to the single imaging location.

Accordingly, the foregoing description describes and illustrates a system and method designed to image up to 4 reticles to a single imaging location, in a manner designed to provide high throughput, with a relatively high resolution, and with substrates (e.g. for forming semiconductor wafers) whose size may approach 450 mm. With the foregoing description in mind, the manner in which the principles of the present invention can be used in various ways to image a substrate will become apparent to those in the art.

1. An imaging optical system comprising up to four reticles, and a catadioptric imaging optics system configured to image a selected one or a plurality of the four reticles to a single imaging location.

2. The imaging optical system of claim 1, wherein the four reticles are grouped into two pairs of reticles, and wherein the catadioptric imaging optics system is configured to image a selected one of each of the two pairs of reticles to the single imaging location.

3. The imaging optical system of claim 2, wherein the catadioptric imaging optics system comprises a pair of switching fold mirrors, each of which is associated with one of the two pairs of reticles, wherein each of the switching fold mirrors has a pair of orientations, and wherein when a folding mirror is in one of the pair of orientations, it is oriented to image one of its associated pair of reticles to the single imaging location.

4. The imaging optical system of claim 2, wherein the catadioptric imaging optics system is configured to enable image fields from 2 of the reticles to be imaged to the single image location in a side by side relation.

5. The imaging optical system of claim 2, wherein the catadioptric imaging optics system is configured to enable reticles with different patterns to be sequentially imaged to the single image location.

6. The imaging optical system of claim 2, wherein the catadioptric imaging optics system includes a pair of arms and a common leg, wherein each arm has (i) at least one concave mirror, (ii) at least one intermediate image in proximity to a fold mirror, to allow light to be incident on and reflected from the concave mirror without obscuration, and (iii) at least one switchable fold mirror in each arm, in proximity to a pupil plane, and wherein the common leg has at least one further intermediate image in proximity to a v-mirror that combines the beams from two arms, where the beam size and shape facilitates the folding of the beams perpendicular to the plane of the two arms.

7. The imaging optical system of claim 2, wherein the catadioptric imaging optics system comprises optics with the prescriptions of FIGS. 6a-6d.

8. The imaging optical system of claim 1, wherein each of the reticles has a rectangular pattern, and the reticles and substrate are oriented to be scanned in a direction parallel to the short dimension of the pattern.

9. The imaging optical system of claim 1, wherein the catadioptric imaging optics system is configured to enable substantially continuous imaging of up to 4 reticles to the single imaging location as a substrate is moved in a single predetermined direction in relation to the single imaging location.

10. The imaging optical system of claim 1 wherein the catadioptric imaging optics system is configured to enable substantially continuous imaging of up to 4 reticles to the single imaging location as a substrate is moved in each of a pair of opposite predetermined directions in relation to the single imaging location.

11. The imaging optical system of claim 1, wherein the catadioptric imaging optics system is configured with a numerical aperture of at least 1.3.

12. An imaging method, comprising providing an imaging optical system comprising up to 4 reticles and a catadioptric imaging optics system configured to image a selected one or a plurality of reticles to a single imaging location, and imaging up to 4 of the reticles to the single imaging location via the catadioptric imaging optics system.

13. The imaging method of claim 12, including providing the imaging system with four reticles that are grouped into two pairs of reticles, configuring the catadioptric imaging optics system to image a selected one of each of the two pairs of reticles to the single imaging location, and imaging selected ones of the two pairs of reticles to the single imaging location via the catadioptric imaging optics system.

14. The imaging method of claim 13, including providing the catadioptric imaging optics system with a pair of switching fold mirrors, each of which is associated with one of the two pairs of reticles, wherein each of the switching fold mirrors has a pair of orientations, and wherein when a folding mirror is in one of the pair of orientations, it is oriented to image one of its associated pair of reticles to the single imaging location.

15. The imaging method of claim 13, including imaging 2 of the reticles to the single imaging location in a side by side relation.

16. The method of claim 13, including sequentially imaging at least 2 reticles with different patterns to the single imaging location.

17. The imaging method of claim 13, including providing the catadioptric imaging optics system with a pair of arms and a common leg, wherein each arm has (i) at least one concave mirror, (ii) at least one intermediate image in proximity to a fold mirror, to allow light to be incident on and reflected from the concave mirror without obscuration, and (iii) at least one switchable fold mirror in each arm, in proximity to a pupil plane, and wherein the common leg has at least one further intermediate image in proximity to a v-mirror that combines the beams from two arms, where the beam size and shape facilitates the folding of the beams perpendicular to the plane of the two arms.

18. The imaging method of claim 13, including providing the catadioptric imaging optics system with optics having the prescriptions of FIGS. 6a-6d.

19. The imaging method of claim 12, wherein each of the reticles has a rectangular pattern, including scanning a reticle in a direction parallel to the short dimension of the pattern.

20. The imaging method of claim 12, including providing substantially continuous imaging of up to 4 reticles to the single imaging location as a substrate is moved in a single predetermined direction in relation to the single imaging location.

21. The imaging method of claim 12 including providing substantially continuous imaging of up to 4 reticles to the single imaging location as a substrate is moved in each of a pair of opposite predetermined directions in relation to the single imaging location.

22. The imaging method of claim 12, including providing the catadioptric imaging optics system is configured with a numerical aperture of at least 1.3.
